(19) United States
(12) Patent Application Publication
(10) Pub. No.: US 2012/0189143 A1
(43) Pub. Date: Jul. 26, 2012

(54) Micromechanical Microphone Device and Method for Producing a Micromechanical Microphone Device

(75) Inventors: Alexander Buhmann, Stuttgart (DE); Ando Feyh, Palo Alto, CA (US)

(73) Assignee: Robert Bosch GmbH, Stuttgart (DE)

(21) Appl. No.: 13/343,532

(22) Filed: Jan. 4, 2012

(30) Foreign Application Priority Data
Jan. 5, 2011 (DE) 10 2011 002 457.3

(51) Int. Cl. H04R 1/00; H01L 21/306

(52) U.S. Cl. 381/174; 438/50; 257/E21.219

(57) ABSTRACT

A micromechanical microphone device includes a membrane that is mounted in an elastically deflectable manner above a substrate and that has at least one gate electrode. The device further includes a source region and a drain region provided in or on the substrate with a channel region therebetween. The channel region is at least partly covered by the gate electrode and is spaced apart from the gate electrode by a gap. The membrane is deflectable under the influence of sound in such a way that the gap is variable.

This application claims priority under 35 U.S.C. §119 to patent application no. DE 10 2011 002 457.3, filed on Jan. 5, 2011 in Germany, the disclosure of which is incorporated herein by reference in its entirety.

### BACKGROUND

The present disclosure relates to a micromechanical microphone device and a method for producing a micromechanical microphone device.

Microphones of MEMS design are usually implemented by means of capacitive transducers. The chip sizes are in the range of 1×1 mm², the miniaturizability of the devices being limited.

It has been known for some time that the deflections of the sound-pressure-sensitive membrane of a micromechanical microphone component can be detected with the aid of a field effect transistor. The lateral dimensions of such a FET for a single detection are very small in comparison with the electrodes of a measuring capacitance having a similar sensitivity. Therefore, the space requirement of a microphone component based on the FET principle is not primarily determined by the dimensions of the FET components, but rather by the type of production process for producing the microphone structure.

US 2003/0137021 A1 discloses an integrated electronic microphone and a corresponding production method. This known microphone comprises a detection electrode, which is formed as part of an elastic membrane, and a counterelectrode in the form of a perforated fixed rear-side plate membrane, wherein the detection electrode is connected to the gate of a detection transistor.

W. Kronast, B. Müller, and A. Stoffel, “A miniaturized single-chip silicon membrane microphone with integrated field-effect transistor,” Journal of Micromechanics and Microengineering, 6 (1996), pages 92 to 94, disclose a moving channel transducer contact for a FET based micromechanical microphone device.

### SUMMARY

The present disclosure provides a micromechanical microphone device and a method for producing a micromechanical microphone device.

The microphone device according to the present disclosure is based on the basis of the moving gate approach and is distinguished by its extreme miniaturizability. Membrane sizes in the range of 30 to 300 μm diameter are conceivable. Chip sizes 0.5×0.5 mm² or smaller including the ASIC can thereby be realized. The features of the disclosure are distinguished, in particular, by high compatibility with regard to CMOS integration.

The concept underlying the present disclosure is the use of a field effect transistor (FET) having a movable gate electrode (moving gate) as a sound/current transducer for an MEMS microphone. The microphone device according to the disclosure is distinguished by very low damping, since there is a possibility of making the diameter of back volume significantly greater than the membrane diameter.

The moving gate transducer concept has a significantly higher sensitivity than other transducer concepts, in particular than the capacitive concept. The sensitive area can be, for example, in the range of less than 100 μm². Capacitive concepts require an area that is larger by three or four orders of magnitude, for example 500,000 μm². This circumstance allows the membrane area to be decoupled from the sensor area. Only two additional masks are necessary in addition to the CMOS process for realizing the moving gate transducer concept. The extremely miniaturizable sensor area associated with the microphone device according to the disclosure allows high functional integration, e.g. the realization of a microphone array on an extremely small area in conjunction with high sensitivity and CMOS integration for use as an acoustic camera.

The small membrane area is distinguished by high robustness since it has a layer thickness of typically 5 to 8 μm and a diameter of typically 30 to 100 μm. The microphone concept according to the disclosure is insensitive and allows simple processing. It has high design freedom when designing the membrane, three to four metal layers, dielectrics and vias typically being involved, which make possible a robust and stress-insensitive membrane.

Preferred features of the disclosure are specified below.

### BRIEF DESCRIPTION OF THE DRAWINGS

Further features and advantages of the present disclosure are explained below with reference to the figures.

In the figures:

FIG. 1 shows a schematic cross-sectional view of a micromechanical microphone device in accordance with one embodiment of the present disclosure;

FIGS. 2a, b show detail enlargements of the region AV in FIG. 1 for elucidating the stages of the production method and of the FET structure of the micromechanical microphone device in accordance with the embodiment of the present disclosure;

FIG. 3 shows a planar cross section of the region AV in FIG. 1 along the top side of the layer 6 in FIGS. 2a, b; and

FIG. 4 shows a partial plan view of the micromechanical microphone device in accordance with the embodiment of the present disclosure.

### DETAILED DESCRIPTION

In the figures, identical reference symbols designate identical or functionally identical elements.

FIG. 1 shows a schematic cross-sectional view of a micromechanical microphone device in accordance with one embodiment of the present disclosure.

In FIG. 1, reference symbol 1 designates a silicon substrate, which has a continuous rear-side trench 2 for the back volume. The rear-side trench 2 can, as necessary, be expanded even further by means of additional etching, as indicated by the dashed line and reference symbol 2′ for an expanded rear-side trench. Reference symbol 3 designates in combination insulation layers and wiring metal layers, and reference symbol 4 designates a movable membrane with an integrated gate connection for realizing the moving gate transducer concept.

The membrane 4, which is elastically movable by sound pressure, has the effect that the gap 14 with respect to the underlying substrate 1 can increase and decrease. A source region, a drain region and a channel region lying therebetween are provided in the substrate 1, wherein the conductivity of the channel region is dependent on the gate voltage present in the membrane 4 and on the instantaneous size of the gap 14. Consequently, mechanical sound oscillations can be converted into corresponding electrical current oscillations.

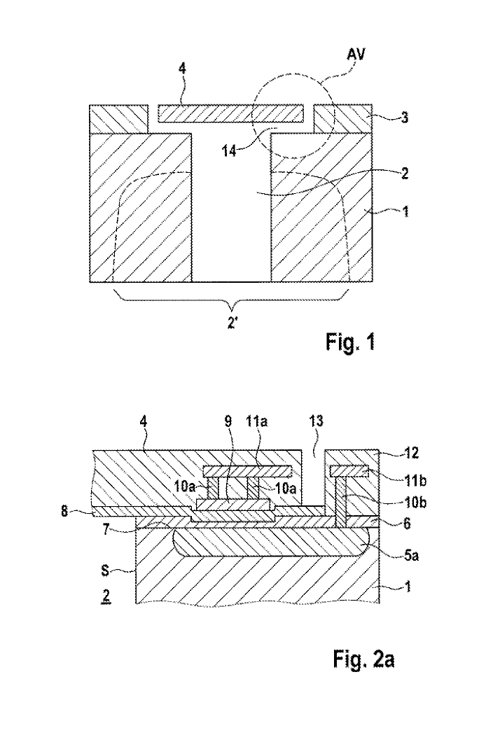

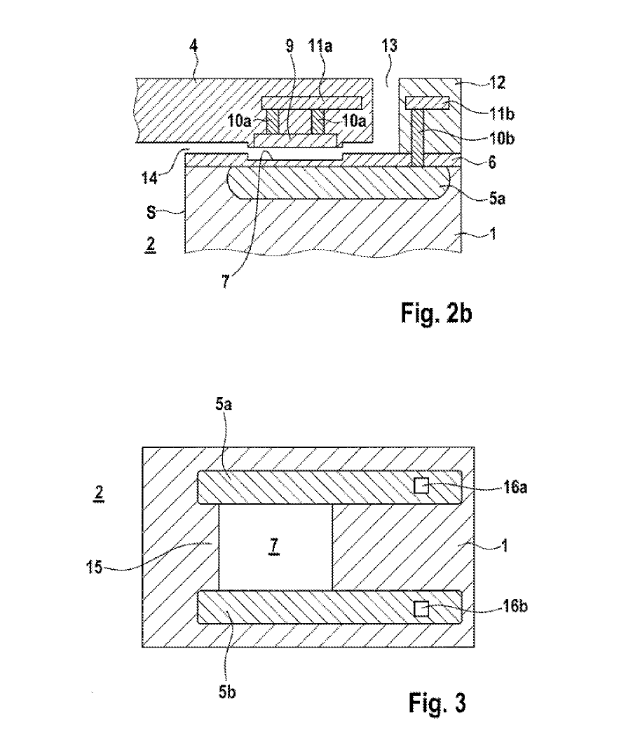

FIGS. 2a, b show detail enlargements of the region AV in FIG. 1 for elucidating the stages of the production method and the FET structure of the micromechanical microphone device in accordance with the embodiment of the present disclosure.

In FIGS. 2a, b, reference symbol 5a designates a source integrated in the substrate 1, said source having been formed in well-type fashion, for example by means of a corresponding diffusion process. After the final processing of the components contained in substrate 1, a field oxide layer 6 having a thickness of a few 100 nm, for example, is grown on the surface of the substrate 1. In the region of the later channel 15, the field oxide layer 6 is removed by means of an etching process, for example and a gate oxide 7 is grown, having a thickness of typically 5 to 20 nm.

Afterward, a polysilicon layer 8 as sacrificial layer having a thickness of typically from 100 to 600 nm, is applied on the field oxide layer 6 and the gate oxide 7. Above the sacrificial layer in the region of the channel 15 and the gate oxide layer 7, a gate electrode 9 composed of polysilicon, for example, is subsequently formed by means of corresponding deposition and etching techniques.

Reference symbols 10a designate metallic vias between the gate electrode 9 and a metal conductor track, designated by reference symbol 11a, for realizing a redistribution wiring. Analogously, reference symbol 10b designates a metallic contact plug for connecting the source 5a to a metal conductor track 11b, which enables the source 5a to be connected by means of the metallic contact plug 10b. The components 9, 10a, 11a, 10b, 11b are embedded in a dielectric insulation layer 12 which consists of silicon oxide, for example. The metallic vias can be embodied from tungsten, for example, and the metallic conductor tracks can be embodied from aluminum, for example.

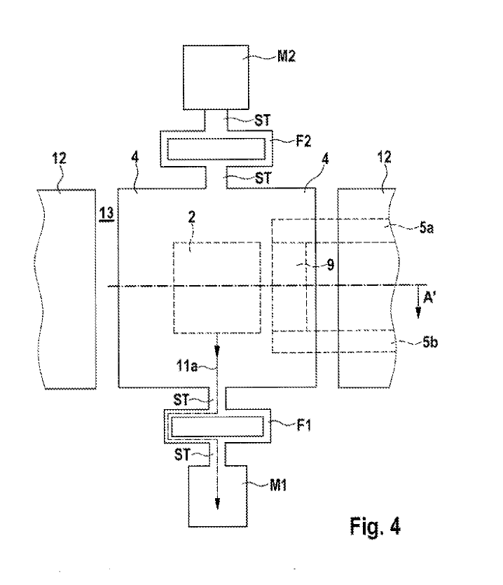

After the formation of the redistribution wiring structures and the dielectric insulation layer 12, a trench 13 is etched, which delimits the majority of the membrane 4 from the surrounding dielectric insulation layer 12 (cf. FIG. 4). This front-side structuring of the movable membrane 4 is preferably effected by means of an anisotropic dry etching process.

In a subsequent etching process, proceeding from the rear side, the rear-side trench 2 is formed by an etching process, wherein the field oxide layer 6 serves as an etching stop. After etching through the substrate 1 from the rear side as far as the field oxide layer 6, it is possible to remove the latter in the region of the rear-side trench 2 by means of a dry etching process selectively with respect to the sacrificial layer 8 composed of polysilicon situated thereabove.

This finally yields the process state shown in FIG. 2a.

FIG. 2b shows the state after sacrificial layer etching has been effected in order to remove the sacrificial layer 8 composed of polysilicon, wherein the sacrificial layer etching is effected for example by means of ClF₃.XeF2 or SF6 in the gas phase or by means of a plasma process. The resulting gap 14 between the gate electrode 9 and the gate oxide 7 constitutes the gate distance in the equilibrium case where no deflection forces act on the movable membrane 4. As necessary, the side wall S of the rear-side trench 2 can be protected by means of an oxide during the sacrificial layer etching, in order to avoid an etching attack during the sacrificial layer etching process in e.g. ClF₃.

Alternatively, it is conceivable firstly to carry out the sacrificial layer etching through the trench 13 only on the front side, wherein either the rear-side trench 2 has already been etched or the rear-side trench 2 is etched only afterward. With this type of process implementation, the protection of the side walls of the rear-side trench 2 can be dispensed with, which possibly leads to a simplified process implementation.

As already mentioned above, in order to improve the damping properties, the rear-side trench can be enlarged by means of a two-stage trench process which is indicated by the dashed line in FIG. 1 and reference symbol 2′. This can readily be realized particularly in the case of the very small size of the membrane 14 that is achievable by means of the moving gate transducer concept proposed. The diameter of the rear-side trench 2′ can thus be significantly greater than the membrane diameter and, in particular, also be extended below the regions in which an evaluation circuit (not shown) is realized. In the case of the conventional construction according to the capacitive transducer concept, this is not possible in a practical manner since the membrane takes up a large part of the total chip area. A corresponding enlargement would lead in this case to difficulties in the construction technology for the sensor element.

In order to avoid a drift in the moving gate transducer concept, reference elements can be provided, for example. This involves comparably embodied field effect transistors without a first polysilicon layer. The latter are sufficiently passivated and mechanically insensitive. Drift, for example as a result of surface charging, can, however, also be filtered out by a sound-sensitive membrane being situated on average always in the equilibrium position. By means of temporal integration of the deflection during operation, drift can thus be detected computationally and be reliably adjusted. This also applies to drift caused by temperature effects.

FIG. 3 shows a planar cross section of the region AV in FIG. 1 along the top side of the layer 6 in FIGS. 2a, b.

In FIG. 3, reference symbol 5b designates the drain, which, like the source 5a, is embodied as a well in the substrate 1. Reference symbol 7 designates the gate oxide lying between source 5a and drain 5b above the channel 15. Contact can be made with the source 5a by means of the contact region 16a and with the drain 5b by means of the contact region 16b, that is to say that corresponding metallic contact plugs 10b can be led upward at this location.

FIG. 4 shows a partial plan view of the micromechanical microphone device in accordance with the embodiment of the present disclosure.

As can be seen in FIG. 4, the trench 13 surrounds virtually the entire movable membrane 4, which is connected only by means of webs ST to a first and second spring device F1, F2, which are in turn connected by means of webs ST to the bases M1, M2 anchored in the substrate. Consequently, the membrane 4 and the spring device F1, F2 are mounted in a suspended manner above the substrate and elastic deflection and restoring of the membrane 4 is made possible.

FIG. 4 additionally illustrates how the metal conductor track 11a, serving as the connection of the gate electrode 9, is routed by means of a conductor track routing—depicted in a dash-dotted manner—by way of the mechanical suspension of the membrane 4 through the spring device F1 and the anchoring M1 outward to the fixed-land region.

Although in the above embodiment, the FET region is provided only one side of the movable membrane 14, it is also possible to position a plurality of FET regions with a movable gate in the membrane, in particular in order to increase the signal. This can proceed to such an extent that the gate region and the corresponding channel region in the substrate 1 are provided in a ring-shaped manner virtually along the entire edge region of the membrane 4.

It is possible to reliably avoid the movable membrane 4 from sticking to the substrate 1 by means of a customary antistiction coating in a manner analogous to that in the case of inertial sensors.

Although the present disclosure has been described above on the basis of preferred exemplary embodiments it is not restricted thereto but rather can be modified in diverse ways.

In particular, the stated materials and geometries are mentioned only by way of example and can be varied diversely.

What is claimed is:

1. A micromechanical microphone device comprising:
a substrate;
a membrane mounted in an elastically deflectable manner above the substrate, the membrane including at least one gate electrode;
a source region and a drain region provided in or on the substrate with a channel region therebetween;
wherein the channel region is at least partly covered by the gate electrode and is spaced apart from the gate electrode by a gap; and
wherein the membrane is deflectable under the influence of sound in such a way that the gap is variable.

2. The microphone device according to claim 1, wherein the substrate defines a continuous rear-side trench provided below the membrane.

3. The microphone device according to claim 2, wherein the rear-side trench is expanded toward the rear side of the substrate.

4. The microphone device according to claim 1, wherein the membrane is anchored by at least one spring device and a base connected thereto in the substrate.

5. The microphone device according to claim 4, further comprising at least one conductor track led by way of the spring device and the base connected thereto to the gate electrode.

6. The microphone device according to claim 1, wherein the gate electrode and the channel region are configured to be in ring-shaped fashion.

7. The microphone device according to claim 1, wherein the membrane has a plurality of gate electrodes and the substrate has a plurality of corresponding source regions and drain regions with a channel region respectively lying therebetween.

8. The microphone device according to claim 1, wherein the source region and the drain region are configured as wells in the substrate.

9. The microphone device according to claim 1, wherein the membrane has an electrical insulation layer, into which the gate electrode is at least partly embedded.

10. A method for producing a micromechanical microphone device, comprising:
forming a source region and a drain region with a channel region lying therebetween in or on a substrate;
forming a sacrificial layer above the structure resulting therefrom;
forming a membrane, which is mounted in regions at the substrate, which has at least one gate electrode above the sacrificial layer, and wherein the channel region at least partly covers by the gate electrode;
sacrificial layer etching of the sacrificial layer such that the membrane is mounted in an elastically deflectable manner above the substrate and is spaced apart from the gate electrode by a gap so that the membrane is deflectable under the influence of sound in such a way that the gap is variable.

11. The method according to claim 10, wherein the substrate defines a continuous rear-side trench formed below the membrane.

12. The method according to claim 11, wherein the rear-side trench is formed in a two-stage etching process in such a way that it is expended toward the rear side of the substrate.

13. The method according to claim 11, wherein the sacrificial layer etching is effected through a trench surrounding the membrane partly on the front side of the substrate, and the rear-side trench is formed after the sacrificial layer etching.

14. The method according to claim 11, wherein the rear-side trench is formed before the sacrificial layer etching, and the sacrificial layer etching is effected through the rear-side trench and through a trench surrounding the membrane partly on the front side of the substrate.

15. The method according to claim 14, wherein the rear-side trench includes side-walls, and wherein the side walls are protected by a protective layer during the sacrificial layer etching.
